(19) United States
(12) Patent Application Publication
(10) Pub. No.: US 2026/0215222 A1
(43) Pub. Date: Jul. 23, 2026

(54) SUBSTRATE PROCESSING APPARATUS

(71) Applicant: SAMSUNG ELECTRONICS CO., LTD., Suwon-si (KR)

(72) Inventors: Jong Ho PARK, Suwon-si (KR); Chan Wook PARK, Suwon-si (KR); Hyun Ho KIM, Suwon-si (KR); Hyung Jun PARK, Suwon-si (KR)

(73) Assignee: SAMSUNG ELECTRONICS CO., LTD., Suwon-si (KR)

(21) Appl. No.: 19/361,590

(22) Filed: Oct. 17, 2025

(30) Foreign Application Priority Data
Jan. 23, 2025 (KR) 10-2025-0010027

(51) Int. Cl. H01L 21/687; H01L 21/67; H01L 21/683

(52) U.S. Cl. CPC H10P 72/7606; H10P 72/0414; H10P 72/7402; H10P 72/78

(57) ABSTRACT

A substrate processing apparatus includes a ring cover that prevents contamination of a ring frame and separation between a wafer and an adhesive tape. The substrate processing apparatus also includes a supporter configured to support a wafer assembly, which includes a ring frame, an adhesive tape fixed to the ring frame, and a wafer attached to the adhesive tape. The ring cover is mounted on the supporter and configured to seal an internal space, in which the ring frame is disposed, by pressurize the wafer. The substrate processing apparatus further includes a spray device configured to spray a cleaning solution onto the wafer.

### CROSS-REFERENCE TO RELATED APPLICATION

This application claims priority from Korean Patent Application No. 10-2025-0010027 filed on Jan. 23, 2025 in the Korean Intellectual Property Office and all the benefits accruing therefrom under 35 U.S.C. 119, the contents of which in its entirety are herein incorporated by reference.

### BACKGROUND

### 1. Technical Field

The present disclosure relates to a substrate processing apparatus.

### 2. Description of the Related Art

In a process of manufacturing a semiconductor device, a cleaning process is performed to remove particles generated in a wafer. The cleaning process is performed by spraying a cleaning solution onto the wafer supported by a supporter. The wafer is attached to an adhesive tape, and is supported by the supporter together with a ring frame for fixing the adhesive tape.

Since the ring frame is a re-use product, it is required to minimize contact with the cleaning solution to prevent contamination. Accordingly, the cleaning process is performed in a state that a ring cover for preventing the cleaning solution from being permeated into the ring frame is mounted on the supporter.

### BRIEF SUMMARY

An object of the present disclosure is to provide a substrate processing apparatus including a ring cover that prevents contamination of a ring frame and separation between a wafer and an adhesive tape.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided a substrate processing apparatus comprising, a supporter configured to support a wafer assembly, wherein the wafer assembly includes a ring frame, an adhesive tape fixed to the ring frame, and a wafer attached to the adhesive tape, a ring cover mounted on the supporter and configured to seal an internal space, in which the ring frame is disposed, by pressurizing the wafer, and a spray device configured to spray a cleaning solution onto the wafer.

According to an aspect of the present disclosure, there is provided a substrate processing apparatus comprising, a housing including a bottom surface and an upper surface, a supporter installed in the housing and configured to support a wafer assembly, wherein the wafer assembly includes a ring frame, an adhesive tape fixed to the ring frame, and a wafer attached to the adhesive tape, a ring cover mounted on the supporter and in contact with the wafer, a spray device configured to spray a cleaning solution onto the wafer, and a discharge hole passing through the bottom surface of the housing for discharging the cleaning solution, wherein the wafer includes a first surface attached to the adhesive tape and a second surface opposite to the first surface, the supporter supports the wafer assembly so that the second surface of the wafer faces the bottom surface of the housing, and the spray device sprays the cleaning solution from a lower portion of the supporter toward the second surface of the wafer.

According to an aspect of the present disclosure, there is provided a substrate processing apparatus comprising, a housing including a bottom surface and an upper surface, a vacuum chuck installed in the housing and configured to adsorb a wafer assembly, wherein the wafer assembly includes a ring frame, an adhesive tape fixed to the ring frame, and a wafer attached to the adhesive tape, and wherein the wafer includes a chip area in which a semiconductor chip is mounted and an edge area surrounding the chip area, a spinner configured to rotate the vacuum chuck, a ring cover mounted on the vacuum chuck, spaced apart from the ring frame and the adhesive tape, and configured to seal an internal space, in which the ring frame is disposed, by pressurizing the edge area of the wafer, a cover clamp installed in the vacuum chuck for fixing the ring cover, a spray device configured to spray a cleaning solution onto the wafer, and a discharge hole passing through the bottom surface of the housing for discharging the cleaning solution, wherein the wafer includes a first surface attached to the adhesive tape and a second surface opposite to the first surface, the vacuum chuck adsorbs the wafer assembly so that the second surface of the wafer faces the bottom surface of the housing, and the spray device sprays the cleaning solution from a lower portion of the vacuum chuck toward the second surface of the wafer.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a conceptual view illustrating a substrate processing apparatus according to some embodiments.

FIG. 2 is a plan view illustrating a wafer assembly of FIG. 1.

FIG. 3 is a cross-sectional view illustrating the substrate processing apparatus of FIG. 1.

FIG. 4 is an enlarged view illustrating an area P of FIG. 3.

FIG. 5 is a perspective view illustrating a ring cover of FIG. 1.

FIG. 6 is a plan view illustrating a ring cover of FIG. 1.

FIGS. 7 to 10 are views illustrating a substrate processing apparatus according to some embodiments.

FIG. 11 is a flow chart illustrating a substrate processing method of a substrate processing apparatus, according to some embodiments.

FIGS. 12 to 15 are views illustrating intermediate steps to describe the substrate processing method of FIG. 11.

### DETAILED DESCRIPTION OF THE DISCLOSURE

It will be understood that, although the terms “first”, “second”, etc. may be used herein to describe various elements, these elements should not be limited by these terms. These terms are only used to distinguish one element from another element. Thus, a first element discussed below could be termed a second element within the technical spirits of the present disclosure.

Hereinafter, embodiments according to the technical spirits of the present disclosure will be described with reference to the accompanying drawings.

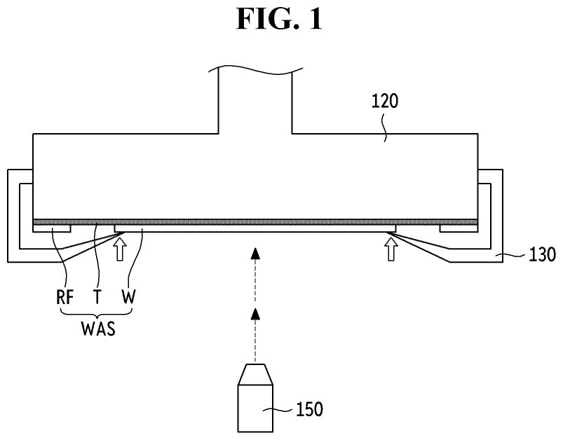

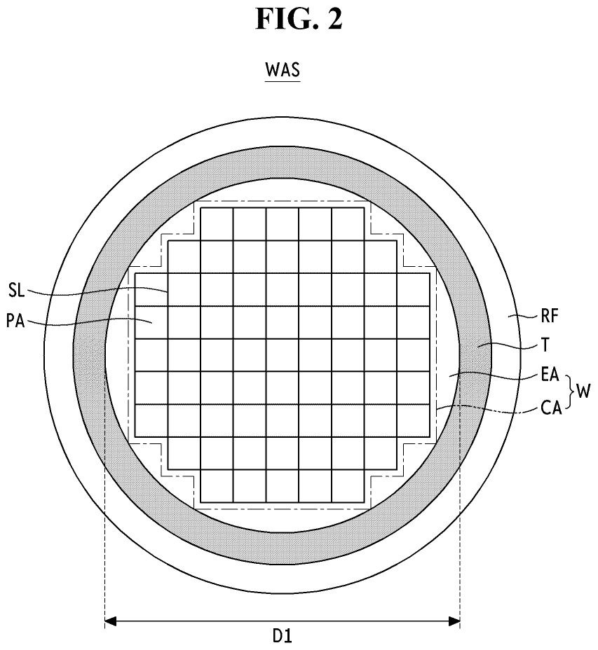

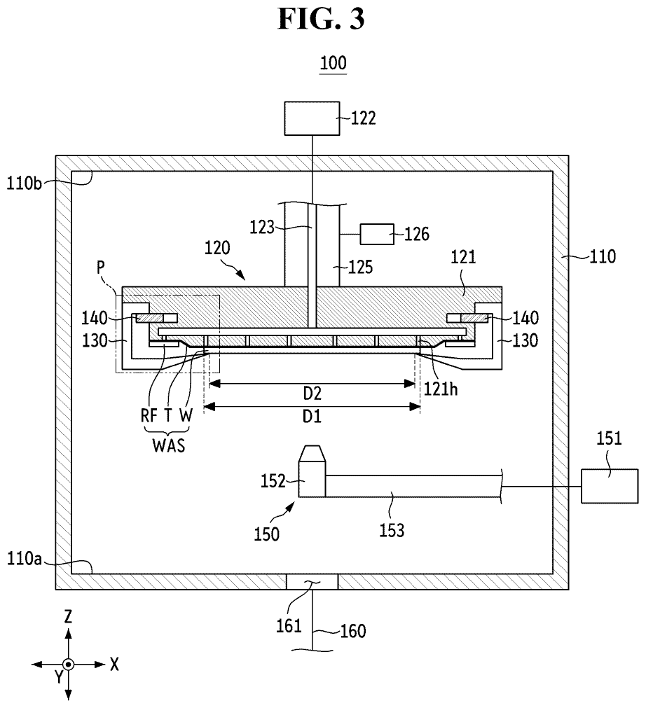

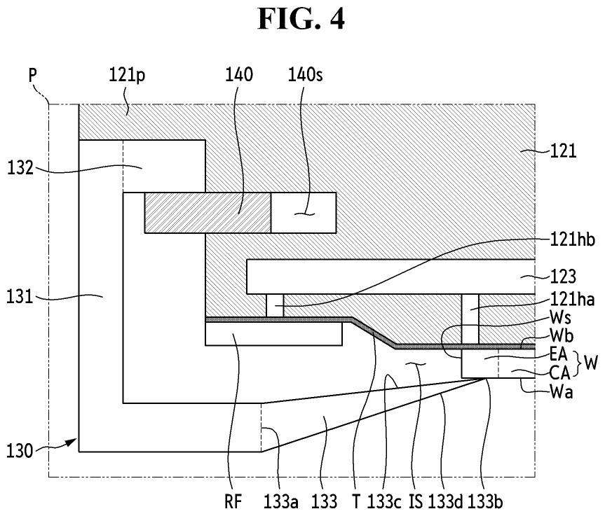

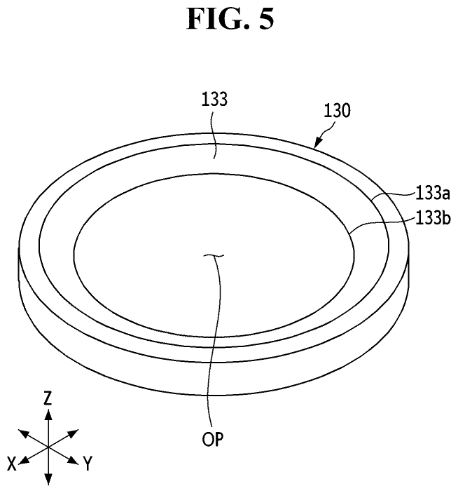

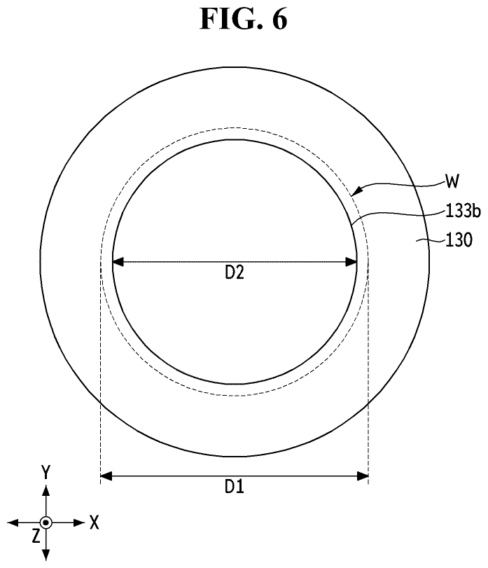

FIG. 1 is a conceptual view illustrating a substrate processing apparatus according to some embodiments. FIG. 2 is a plan view illustrating a wafer assembly of FIG. 1. FIG. 3 is a cross-sectional view illustrating the substrate processing apparatus of FIG. 1. FIG. 4 is an enlarged view illustrating an area P of FIG. 3. FIG. 5 is a perspective view illustrating a ring cover of FIG. 1. FIG. 6 is a plan view illustrating a ring cover of FIG. 1.

Referring to FIGS. 1 to 6, a substrate processing apparatus 100 according to some embodiments may include a housing 110, a supporter 120, a ring cover 130, a cover clamp 140, a spray device 150, and a discharge pipe 160.

The housing 110 provides an inner space for performing a cleaning process for a wafer W. The housing 110 includes a bottom surface 110a and an upper surface 110b, which are opposite to each other in a vertical direction Z. The vertical direction Z may be a direction perpendicular to the ground. Each of a first horizontal direction X and a second horizontal direction Y may be orthogonal to the vertical direction Z. The first horizontal direction X may cross the second horizontal direction Y.

The supporter 120 is installed in the housing 110. The supporter 120 is configured to support a wafer assembly WAS. The supporter 120 is configured to rotate the wafer assembly WAS.

The wafer assembly WAS includes a wafer W, an adhesive tape T, and a ring frame RF. The wafer W and the ring frame RF are attached to the same surface of the adhesive tape T. The ring frame RF surrounds the wafer W. The ring frame RF fixes the adhesive tape T. As the ring frame RF fixes a shape of the adhesive tape T, an adhesive force between the wafer W and the adhesive tape T may be strengthened. The ring frame RF includes metal such as stainless steel.

The wafer W may be a package substrate for manufacturing a semiconductor package. The wafer W may have a disk shape. The wafer W may include a chip area CA and an edge area EA. The chip area CA may be an area in which a plurality of semiconductor chips are mounted. The edge area EA may be an area surrounding the chip area CA. The chip area CA may include a plurality of package areas PA and a plurality of scribe lanes SL. Each package area PA may be defined by the scribe lane SL. One or more semiconductor chips may be mounted in each package area PA.

The wafer W includes a first surface Wa, a second surface Wb, and a sidewall Ws. The first surface Wa of the wafer W and the second surface Wb of the wafer W are opposite to each other in the vertical direction Z. The second surface Wb of the wafer W is a surface attached to the adhesive tape T. The sidewall Ws of the wafer W connects the first surface Wa of the wafer W to the second surface Wb of the wafer W. The supporter 120 may support the wafer assembly WAS such that the first surface Wa of the wafer W faces the bottom surface 110a of the housing 110.

The supporter 120 includes a vacuum chuck 121 and a spinner 125. The vacuum chuck 121 may have a disk shape. The vacuum chuck 121 may be configured to adsorb the wafer assembly WAS.

In detail, a vacuum pipe 123 is installed in the vacuum chuck 121. The vacuum pipe 123 is connected to a vacuum pump 122 by passing through the spinner. The vacuum pump 122 may make the inside of the vacuum pipe 123 into a vacuum state. The vacuum chuck 121 includes a plurality of vacuum holes 121h connected to the vacuum pipe 122. The vacuum hole 121h may be a passage through which the air moves. The air may move from the outside of the vacuum chuck 121 to the vacuum pipe 123 due to a pressure difference. As the air moves to the vacuum pipe 123 through the vacuum hole 121h, the vacuum chuck 121 may adsorb the wafer assembly WAS. The vacuum chuck 121 may adsorb the wafer assembly WAS such that the first surface Wa of the wafer W faces the bottom surface 110a of the housing 110.

The vacuum hole 121h includes a first vacuum hole 121ha and a second vacuum hole 121hb. The first vacuum hole 121ha may be disposed at a position corresponding to the wafer W to adsorb the wafer W. The second vacuum hole 121hb may be disposed at a position corresponding to the ring frame RF to adsorb the ring frame RF. As the vacuum hole 121h is disposed at positions corresponding to the wafer W and the ring frame RF, respectively, the wafer assembly WAS may be stably adsorbed to the vacuum chuck 121.

The spinner 125 may be installed on the vacuum chuck 121. The spinner 125 may be installed above the vacuum chuck 121. The spinner 125 may be more adjacent to the upper surface 110b of the housing 110 than the vacuum chuck 121. The vacuum chuck 121 may include a bottom surface and an upper surface, which are opposite to each other in the vertical direction Z. The bottom surface of the vacuum chuck 121 may be an adsorption surface that adsorbs the wafer assembly WAS. The adsorption surface of the vacuum chuck 121 faces the bottom surface 110a of the housing 110. The spinner 125 may be installed on the upper surface of the vacuum chuck 121. The spinner 125 may have a cylindrical shape.

The spinner 125 may be configured to rotate the vacuum chuck 121. The spinner 125 may be rotated by a rotating motor 126. The vacuum chuck 121 connected to the spinner 125 may rotate together with the spinner 125 as the spinner 125 rotates. The wafer assembly WAS adsorbed to the vacuum chuck 121 may rotate together with the vacuum chuck 121.

The ring cover 130 may be attached to or detached from the supporter 121. The ring cover 130 may be configured to seal the ring frame RF. The ring cover 130 may be configured to seal an inner space IS. The inner space IS may be defined by the supporter 120, the ring cover 130, and the wafer assembly WAS. The ring frame RF is disposed on the inner space IS. The ring cover 130 may surround the supporter 120. The ring cover 130 may be in contact with the edge area EA of the wafer W. The ring cover 130 may pressurize the edge area EA of the wafer W.

In some embodiments, the ring cover 130 may be in contact with the first surface Wa of the wafer W. The ring cover 130 may pressurize the first surface Wa of the wafer W.

The ring cover 130 may be spaced apart from the adsorption surface of the vacuum chuck 121. The ring cover 130 is spaced apart from the adhesive tape T. The ring cover 130 is not in contact with the adhesive tape T. The ring cover 130 may be spaced apart from the ring frame RF.

The ring cover 130 includes a body 131, a locking portion 132, and a pressurizing portion 133. The body 131, the locking portion 132 and the pressurizing portion 133 may be integrally formed. The body 131, the locking portion 132 and the pressurizing portion 133 may be formed of the same material.

The body 131 may surround a sidewall of the vacuum chuck 121. The body 131 may be spaced apart from the vacuum chuck 121.

The locking portion 132 may be extended from one end of the body 131 toward the center of the ring cover 130. The locking portion 132 may be extended from one end of the body 131 toward the sidewall of the vacuum chuck 121. The locking portion 132 may be extended from one end of the body 131 in the first horizontal direction X. The locking portion 132 may be in contact with the sidewall of the vacuum chuck 121.

The pressurizing portion 133 may be extended from the other end of the body 131 toward the center of the ring cover 130. The pressurizing portion 133 is spaced apart from the adsorption surface of the vacuum chuck 121. The pressurizing portion 133 may be in contact with the wafer W. The pressurizing portion 133 may pressurize the wafer W. The pressurizing portion 133 is spaced apart from the adhesive tape T. The pressurizing portion 133 is not in contact with the adhesive tape T. The pressurizing portion 133 may be spaced apart from the ring frame RF.

The pressurizing portion 133 includes one end 133a and the other end 133b, which are opposite to each other. One end 133a of the pressurizing portion 133 is connected to the body 131. One end 133a of the pressurizing portion 133 may be the same as the other end of the body 131. In some embodiments, the other end 133b of the pressurizing portion 133 may be in contact with the edge area EA of the wafer W.

The pressurizing portion 133 includes an inner surface 133c and an outer surface 133d, which are opposite to each other. Each of the inner surface 133c and the outer surface 133d of the pressurizing portion 133 connects one end 133a with the other end 133b of the pressurizing portion 133. The inner surface 133c of the pressurizing portion 133 is more adjacent to the vacuum chuck 121 than the outer surface 133d of the pressurizing portion 133.

In some embodiments, the pressurizing portion 133 may be in contact with the first surface Wa of the wafer W. The pressurizing portion 133 may pressurize the first surface Wa of the wafer W.

In some embodiments, the pressurizing portion 133 may be obliquely extended from the other end of the body 131 toward the adsorption surface of the vacuum chuck 121. A thickness of the pressurizing portion 133 may be reduced as the pressurizing portion 133 becomes far from the body 131. The thickness of the pressurizing portion 133 may be reduced from one end 133a of the pressurizing portion 133 toward the other end 133b of the pressurizing portion 133.

The ring cover 130 includes an opening OP defined by the pressurizing portion 133. The opening OP may be defined by the other end 133b of the pressurizing portion 133. A diameter D2 of the opening OP may be smaller than a diameter D1 of the wafer W.

The cover clamp 140 may be installed in the vacuum chuck 121. The cover clamp 140 may fix the ring cover 130 to the vacuum chuck 121. The ring cover 130 may be mounted on the vacuum chuck 121 by the cover clamp 140. The cover clamp 140 is preferably installed at a position at which the ring cover 130 pressurizes the wafer W and at the same time may be fixed to the vacuum chuck 121.

A portion of the cover clamp 140 may be protruded from the sidewall of the vacuum chuck 121. A portion of the cover clamp 140 may be disposed in the inner space IS. The cover clamp 140 may be in contact with the inner surface of the ring cover 130. The cover clamp 140 may be in contact with the locking portion 132 of the ring cover 130. The cover clamp 140 may support the locking portion 132 of the ring cover 130.

The cover clamp 140 may move inside and outside the vacuum chuck 121. A moving space 140s in which the cover clamp 140 may move is formed in the vacuum chuck 121. The cover clamp 140 may be driven to be protruded from the sidewall of the vacuum chuck 121. The cover clamp 140 may be driven to be inserted into the vacuum chuck 121. Since the cover clamp 140 may be driven to be protruded from the vacuum chuck 121 or to be inserted into the vacuum chuck 121, the ring cover 130 may be mounted on the vacuum chuck 121 or may be detached from the vacuum chuck 121.

The vacuum chuck 121 includes a protrusion portion 121p for guiding the mounting of the ring cover 130. The protrusion portion 121p may be protruded from the sidewall of the vacuum chuck 121. In order for the ring cover 130 to be mounted on the vacuum chuck 121, the ring cover 130 needs to ascend along the sidewall of the vacuum chuck 121. In order to fix the ring cover 130, the cover clamp 140 needs to be driven to be protruded from the vacuum chuck 121 and be disposed in the inner space IS. As the ring cover 130 ascends along the sidewall of the vacuum chuck 121, the ring cover 130 may be in contact with the protrusion portion 121p. The position at which the ring cover 130 is in contact with the protrusion portion 121p may be a position at which the cover clamp 140 fixes the ring cover 130 and at the same time the ring cover 130 may pressurize the wafer W.

The spray device 150 may be configured to spray a cleaning solution onto the wafer W. The spray device 150 may spray the cleaning solution onto the first surface Wa of the wafer W from a lower portion of the supporter 120. The cleaning solution may include, for example, at least one of a photoresist stripper, a wet etchant, or a first standard clean 1 (SC1), but is not limited thereto.

The spray device 150 includes a cleaning tank 151, a nozzle 152, and an arm 153. The cleaning tank 151 may supply a cleaning solution. The nozzle 152 may spray the cleaning solution. The nozzle 152 faces the upper surface 110b of the housing 110. The arm 153 may move the nozzle 152 to a lower portion of the vacuum chuck 121.

A discharge hole 161 is installed on the bottom surface 110a of the housing 110. The vacuum chuck 121 is disposed between the discharge hole 161 and the spinner 125. The adsorption surface of the vacuum chuck 121 may face the discharge hole 161. The spray device 150 may be disposed between the discharge hole 161 and the supporter 120. The discharge hole 161 is connected to the discharge pipe 160 by passing through the housing 110. The discharge hole 161 and the discharge pipe 160 may discharge the cleaning solution to the outside of the housing 110.

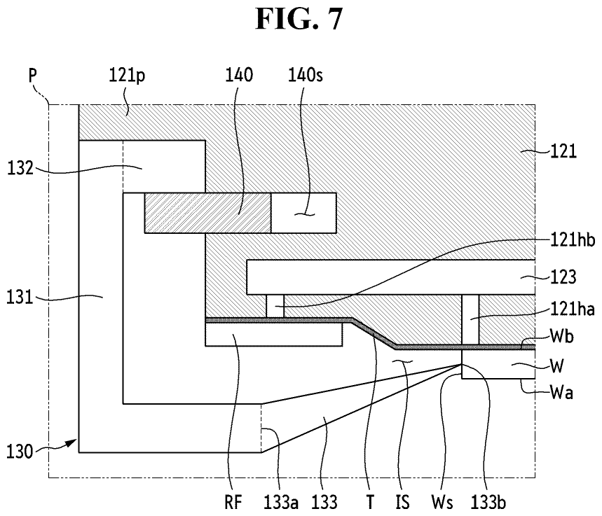

FIGS. 7 to 10 are views illustrating a substrate processing apparatus according to some embodiments. For reference, FIGS. 7 to 10 are enlarged views illustrating an area P of FIG. 3.

Referring to FIG. 7, in some embodiments, the ring cover 130 may be in contact with the sidewall Ws of the wafer W. The ring cover 130 may pressurize the sidewall Ws of the wafer W. In detail, the pressurizing portion 133 may be in contact with the sidewall Ws of the wafer W. The pressurizing portion 133 may pressurize the sidewall Ws of the wafer W.

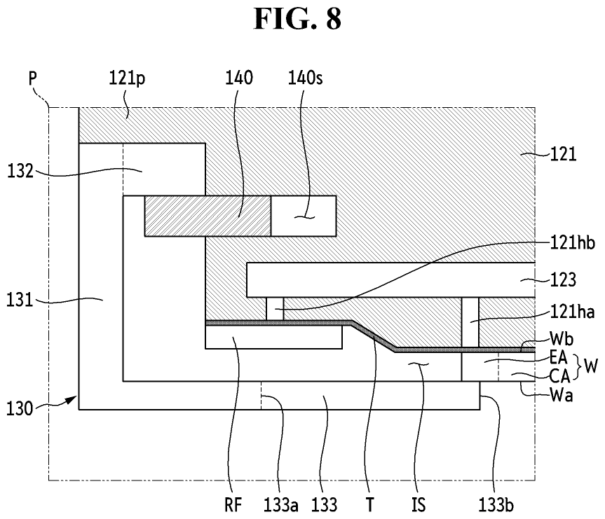

Referring to FIG. 8, in some embodiments, the pressurizing portion 133 may be extended in parallel with the locking portion 132. The pressurizing portion 133 may be extended from the body 131 in the first horizontal direction X. The thickness of the pressurizing portion 133 may be constant. A thickness of the other end 133b of the pressurizing portion 133 may be the same as that of one end 133a of the pressurizing portion 133.

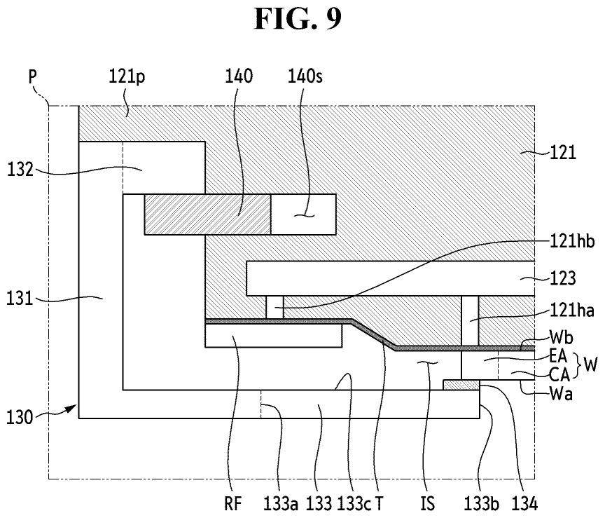

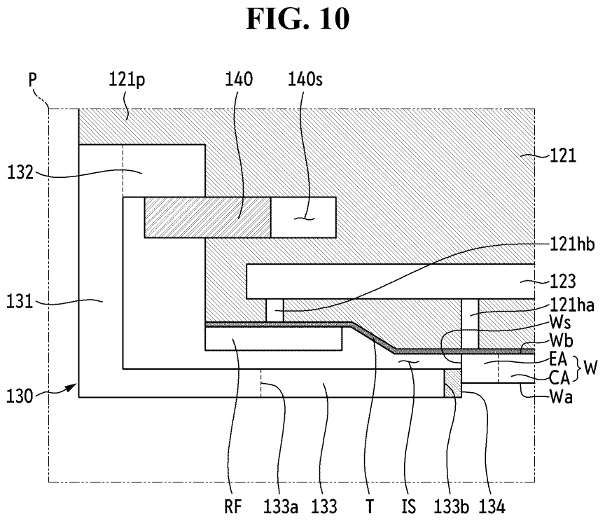

Referring to FIGS. 9 and 10, in some embodiments, the ring cover 130 may further include a sealing member 134.

The sealing member 134 may be installed on the pressurizing portion 133. The sealing member 134 may be in contact with the edge area EA of the wafer W. The sealing member 134 may pressurize the edge area EA of the wafer W.

The sealing member 134 is spaced apart from the vacuum chuck 121. The sealing member 134 is spaced apart from the adhesive tape T. The sealing member 134 may be spaced apart from the ring frame RF.

A material of the sealing member 134 may be different from a material of the body 131, the locking portion 132 and the pressurizing portion 133. The sealing member 134 may include synthetic rubber.

Referring to FIG. 9, the sealing member 134 may be installed on the inner surface 133c of the pressurizing portion 133. The sealing member 134 may be in contact with the first surface Wa of the wafer W. The sealing member 134 may pressurize the first surface Wa of the wafer W.

Referring to FIG. 10, the sealing member 134 may be installed at the other end 133b of the pressurizing portion 133. The sealing member 134 may be in contact with the sidewall Ws of the wafer W. The sealing member 134 may pressurize the sidewall Ws of the wafer W.

The cleaning solution which has cleaned the wafer W may include particles. When the cleaning solution including particles comes into contact with the ring frame RF, the ring frame RF may be contaminated. The substrate processing apparatus 100 according to some embodiments of the present disclosure includes a ring cover 130. The ring cover 130 may seal the ring frame RF to prevent the ring frame RF from being contaminated by the cleaning solution including particles.

The ring cover 130 according to some embodiments of the present disclosure does not pressurize the adhesive tape T but pressurizes the edge area EA of the wafer W, thereby preventing the adhesive tape T from being separated from the wafer W. Therefore, the cleaning solution may be prevented from being permeated between the adhesive tape T and the wafer W. In addition, since the ring cover 130 pressurizes the wafer W, the adhesive force between the adhesive tape T and the wafer W may be improved.

Since the substrate processing apparatus 100 according to some embodiments of the present disclosure flip the supporter 120 and sprays the cleaning solution onto the wafer W from the lower portion of the supporter 120, the cleaning solution may be effectively prevented from being permeated into the ring frame RF. In detail, the vacuum chuck 121 is disposed such that the adsorption surface of the vacuum chuck 121 adsorbing the wafer assembly WAS faces the bottom surface 110a of the housing 110. The spray device 150 sprays the cleaning solution onto the wafer W from the lower portion of the vacuum chuck 121. Therefore, since the cleaning solution sprayed onto the wafer W falls onto the bottom surface 110a of the housing 110 by gravity, the cleaning solution may not be permeated into the ring frame RF along the wafer W and the adhesive tape T.

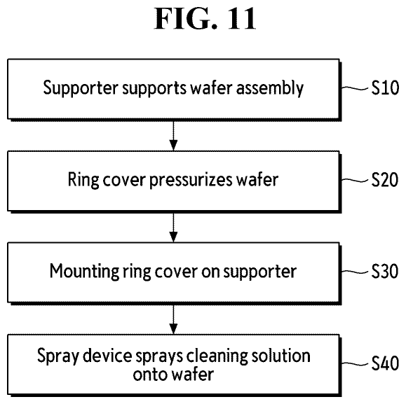

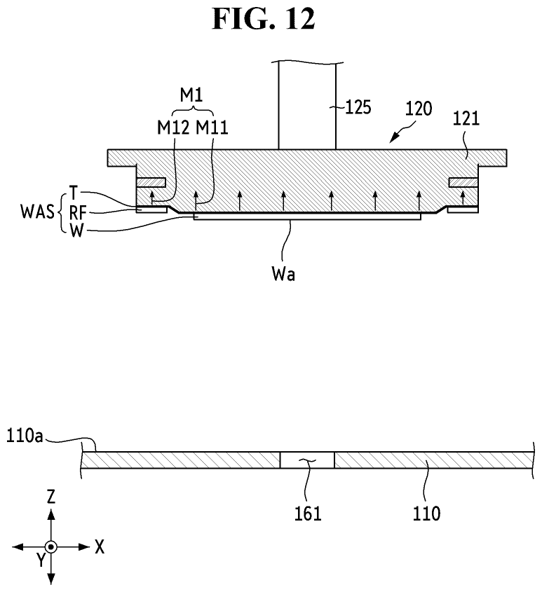

FIG. 11 is a flow chart illustrating a substrate processing method of a substrate processing apparatus, according to some embodiments. FIGS. 12 to 15 are views illustrating intermediate steps to describe the substrate processing method of FIG. 11. For convenience of description, redundant portions of those described with reference to FIGS. 1 to 6 will be briefly described or omitted.

Referring to FIGS. 11 and 12, the supporter supports a wafer assembly (S10).

The supporter 120 supports the wafer assembly WAS such that the first surface Wa of the wafer W faces the bottom surface 110a of the housing 110. First, the wafer assembly WAS moves to the lower portion of the supporter 120, and thus is disposed on the bottom surface of the vacuum chuck 121. Then, the vacuum chuck 121 adsorbs the wafer assembly WAS (see M1). In detail, the vacuum chuck 121 adsorbs the wafer W through the first vacuum hole (121ha of FIG. 4) (see M11 of FIG. 12), and adsorbs the ring frame RF through the second vacuum hole (121hb of FIG. 4). As the vacuum chuck 121 adsorbs the wafer assembly WAS, the wafer assembly WAS may be supported by the supporter 120 without falling onto the bottom surface 110a of the housing 110.

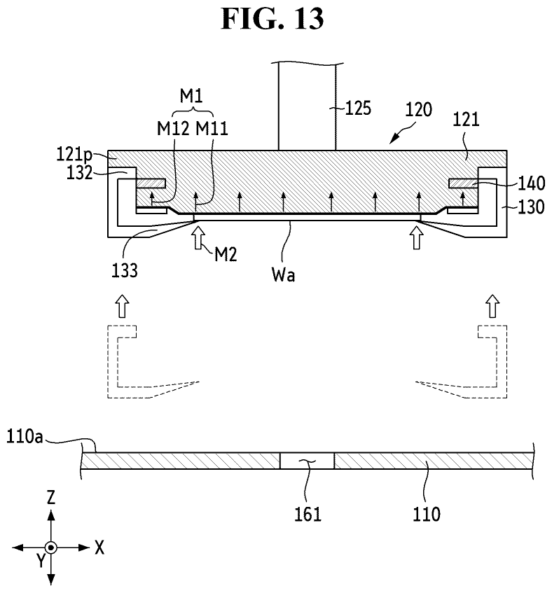

Referring to FIGS. 11 and 13, the ring cover pressurizes the wafer (S20).

The ring cover 130 is disposed to surround the vacuum chuck 121 by ascending along the sidewall of the vacuum chuck 121 from the lower portion of the supporter 120. As the ring cover 130 ascends along the sidewall of the vacuum chuck 121, the pressurizing portion 133 of the ring cover 130 pressurizes the wafer W (see M2 of FIG. 13). The pressurizing portion 133 pressurizes the edge area EA of the wafer W. In some embodiments, the ring cover 130 may be in contact with the first surface Wa of the wafer W. In some embodiments, the ring cover 130 may be in contact with the sidewall Ws of the wafer W.

As the ring cover 130 pressurizes the wafer W, the inner space in which the ring frame RF is disposed may be sealed.

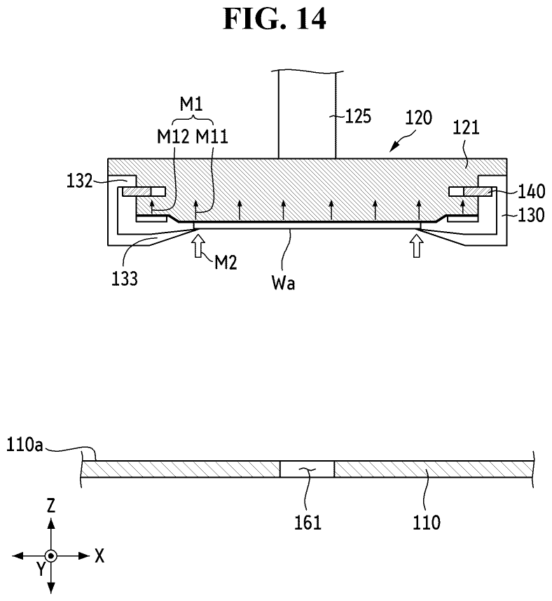

Referring to FIGS. 11 and 14, mounting the ring cover on the supporter (S30).

The cover clamp 140 is driven to be protruded from the sidewall of the vacuum chuck 121 and supports the ring cover 130. In detail, the cover clamp 140 supports the locking portion 132 of the ring cover 130 in contact with the locking portion 132 of the ring cover 130.

The position of the ring cover 130 may be fixed by the cover clamp 140, and accordingly, the ring cover 130 may be mounted on the supporter 120. The ring cover 130 may be mounted on the supporter 120 while pressurizing the wafer W. The protrusion portion 121p of the vacuum chuck 121 may guide the mounting of the ring cover 130.

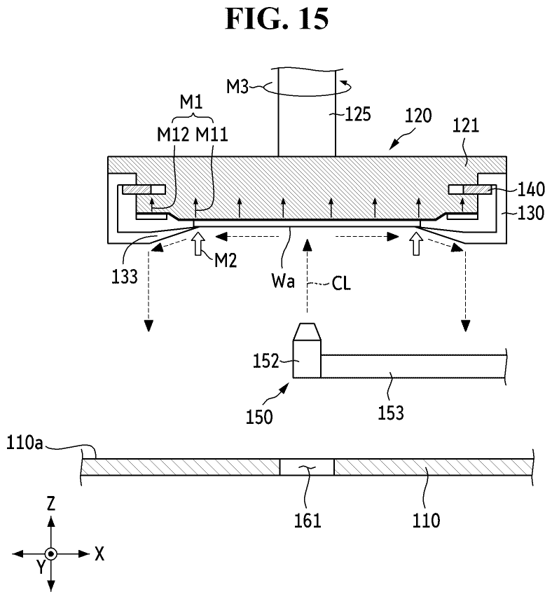

Referring to FIGS. 11 and 15, the spray device sprays the cleaning solution onto the wafer (S40).

First, the nozzle 152 moves to the lower portion of the vacuum chuck 121. The nozzle 152 may move to the lower portion of the vacuum chuck 121 by the arm 153.

Subsequently, a cleaning process is performed for the wafer W. The spray device 150 sprays the cleaning solution CL onto the first surface Wa of the wafer W. The vacuum chuck 121 rotates by the spinner 125 (see M3 of FIG. 15). As the vacuum chuck 121 rotates, the wafer assembly WAS adsorbed to the vacuum chuck 121 may also rotate together.

The cleaning solution CL sprayed onto the wafer W may fall onto the bottom surface 110a of the housing 110 by gravity. The cleaning solution CL including particles by cleaning the wafer W may move along the outer surface of the ring cover 130 and fall onto the bottom surface 110a of the housing 110, and then may be discharged through the discharge hole 161.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A substrate processing apparatus comprising:
a supporter configured to support a wafer assembly, wherein the wafer assembly includes a ring frame, an adhesive tape fixed to the ring frame, and a wafer attached to the adhesive tape;
a ring cover mounted on the supporter and configured to seal an internal space, in which the ring frame is disposed, by pressurizing the wafer; and
a spray device configured to spray a cleaning solution onto the wafer.

2. The substrate processing apparatus of claim 1, wherein the wafer includes a chip area in which a semiconductor chip is mounted and an edge area surrounding the chip area, and
the ring cover is in contact with the edge area of the wafer.

3. The substrate processing apparatus of claim 2, wherein the wafer includes a first surface attached to the adhesive tape and a second surface opposite to the first surface, and
the ring cover pressurizes the second surface of the wafer.

4. The substrate processing apparatus of claim 1, wherein the ring cover is in contact with a sidewall of the wafer.

5. The substrate processing apparatus of claim 1, wherein the ring cover is spaced apart from the adhesive tape and the ring frame.

6. The substrate processing apparatus of claim 1, wherein the ring cover includes a body surrounding a sidewall of the supporter, and a pressurizing portion extending inward from the body.

7. The substrate processing apparatus of claim 6, wherein the pressurizing portion is in contact with the wafer.

8. The substrate processing apparatus of claim 6, wherein the ring cover includes an opening defined by the pressurizing portion, and a diameter of the opening of the ring cover is smaller than a diameter of the wafer.

9. The substrate processing apparatus of claim 6, wherein the ring cover further includes a sealing member installed on the pressurizing portion and in contact with the wafer.

10. The substrate processing apparatus of claim 1, further comprising a cover clamp installed in the supporter for fixing the ring cover,
wherein the ring cover includes a body surrounding a sidewall of the supporter and a locking portion extended from the body toward the sidewall of the supporter, and
the cover clamp supports the locking portion.

11. The substrate processing apparatus of claim 1, wherein the supporter includes a vacuum chuck configured to adsorb the wafer assembly, and a spinner configured to rotate the vacuum chuck.

12. A substrate processing apparatus comprising:
a housing including a bottom surface and an upper surface;
a supporter installed in the housing and configured to support a wafer assembly, wherein the wafer assembly includes a ring frame, an adhesive tape fixed to the ring frame, and a wafer attached to the adhesive tape;
a ring cover mounted on the supporter and in contact with the wafer;
a spray device configured to spray a cleaning solution onto the wafer; and
a discharge hole passing through the bottom surface of the housing for discharging the cleaning solution,
wherein the wafer includes a first surface attached to the adhesive tape and a second surface opposite to the first surface,
the supporter supports the wafer assembly so that the second surface of the wafer faces the bottom surface of the housing, and
the spray device sprays the cleaning solution from a lower portion of the supporter toward the second surface of the wafer.

13. The substrate processing apparatus of claim 12, wherein the ring cover seals an inner space defined by the supporter, the wafer assembly, and the ring cover.

14. The substrate processing apparatus of claim 12, wherein the wafer includes a chip area in which a semiconductor chip is mounted, and an edge area surrounding the chip area, and
the ring cover pressurizes the edge area of the wafer.

15. The substrate processing apparatus of claim 12, wherein the ring cover is spaced apart from the adhesive tape and the ring frame.

16. The substrate processing apparatus of claim 12, wherein the ring cover includes a body surrounding a sidewall of the supporter, and a pressurizing portion extending inward from the body and in contact with the wafer.

17. The substrate processing apparatus of claim 16, wherein the ring cover includes an opening defined by the pressurizing portion, and
a diameter of the opening is smaller than a diameter of the wafer.

18. The substrate processing apparatus of claim 12, wherein the supporter includes a vacuum chuck configured to adsorb the wafer assembly and a spinner configured to rotate the vacuum chuck, and
the vacuum chuck is disposed between the spinner and the discharge hole.

19. The substrate processing apparatus of claim 12, further comprising a cover clamp installed in the supporter for fixing the ring cover,
wherein the ring cover includes a body surrounding a sidewall of the supporter and a locking portion extended from the body toward the sidewall of the supporter, and
the cover clamp supports the locking portion.

20. A substrate processing apparatus comprising:
a housing including a bottom surface and an upper surface;
a vacuum chuck installed in the housing and configured to adsorb a wafer assembly, wherein the wafer assembly includes a ring frame, an adhesive tape fixed to the ring frame, and a wafer attached to the adhesive tape, and wherein the wafer includes a chip area in which a semiconductor chip is mounted and an edge area surrounding the chip area;
a spinner configured to rotate the vacuum chuck;
a ring cover mounted on the vacuum chuck, spaced apart from the ring frame and the adhesive tape, and configured to seal an internal space, in which the ring frame is disposed, by pressurizing the edge area of the wafer;
a cover clamp installed in the vacuum chuck for fixing the ring cover;
a spray device configured to spray a cleaning solution onto the wafer; and
a discharge hole passing through the bottom surface of the housing for discharging the cleaning solution,
wherein the wafer includes a first surface attached to the adhesive tape and a second surface opposite to the first surface,
the vacuum chuck adsorbs the wafer assembly so that the second surface of the wafer faces the bottom surface of the housing, and
the spray device sprays the cleaning solution from a lower portion of the vacuum chuck toward the second surface of the wafer.
